(19) United States
(12) Patent Application Publication
(10) Pub. No.: US 2024/0088612 A1
(43) Pub. Date: Mar. 14, 2024

(54) SYSTEM AND OPERATING METHOD WITH AUTOMATIC SUBASSEMBLY POSITION DETECTION

(71) Applicants: FCI CONNECTORS DONGGUAN LTD., Dongguan City (CN); Alibaba Cloud Computing Ltd., Hangzhou City (CN)

(72) Inventors: Yi-Lin Liu, Dongguan City (CN); Yu-Lin Rao, Dongguan City (CN); Honghao Cao, Shenzhen (CN)

(73) Assignees: FCI CONNECTORS DONGGUAN LTD., Dongguan City (CN); Alibaba Cloud Computing Ltd., Hangzhou City (CN)

(21) Appl. No.: 18/465,544

(22) Filed: Sep. 12, 2023

(30) Foreign Application Priority Data
Sep. 14, 2022 (CN) 202211114266.X

(51) Int. Cl. H01R 13/641; H01R 12/70; H01R 13/642; H01R 25/16

(52) U.S. Cl. CPC H01R 13/641; H01R 12/7088; H01R 13/642; H01R 25/162

(57) ABSTRACT

System and method to use position information about a power supply unit (PSU) within a system for status reporting or control. The system may have multiple slots into which the PSU may be installed, and each of multiple PSUs installed may sense position information, such as an indication of the slot into which it is installed. A controller may receive the position information in connection with status information such that faults or other events associated with a PSU may be reported to a system operator in connection with a position of the affected PSU. The controller may determine adjustments to operating parameters of the PSUs that are impacted by position and may direct commends to the appropriate PSU based on the position information.

### RELATED APPLICATION

This application claims priority to and the benefit of Chinese Patent Application Serial number 202211114266.X, filed Sep. 14, 2022, which is herein incorporated by reference in its entirety.

### FIELD

This application relates generally to electrical interconnection system, such as those including electrical connectors, used to interconnect electronic assemblies.

### BACKGROUND

An electronic system may be assembled from multiple components inserted into a support structure, which may include a rack that has multiple slots. Each of the slots may accept a subassembly, which may be connected through a printed circuit board, referred to as a backplane, or cables that are positioned so that they can engage each of the multiple subassemblies inserted into a slot through separable connectors. The backplane or the cables provide signal connections among the subassemblies installed in the rack. The specific subassemblies inserted into the rack may be selected based on the intended function of the system. Subassemblies may be configured as or include servers, memory, network interfaces, or line interfaces, for example.

One or more of the subassemblies may be a power supply unit (PSU). The PSU may condition and supply power usable by other subassemblies in a rack or outside the rack. For example, electronic systems used in data centers or server farms or systems configured as energy storage cabinets usually contain multiple PSUs. The rack may include one or more busbars that deliver power to the PSUs. The busbar may extend through the rack intersecting multiple slots in the rack, such that each of the PSUs in the rack can connect to the busbars. Busbar connectors, such as connectors sold under the trade name BARKLIP by Amphenol corporation, may be used to connect the PSUs to the busbars, such that the PSUs can take power from the busbars.

### BRIEF SUMMARY

Aspects of the present disclosure relate to improved interconnection systems, particularly portions of the interconnection system that supply power from busbars to electronic components on printed circuit boards.

Some embodiments relate to an electrical connector configured for mating with a mating structure. The electrical connector may include a housing; a first type conductor coupled to the housing; and a plurality of second type conductors, each of the plurality of second type conductors comprising a contact comprising a compliant beam with a first contact portion and a second contact portion. The contact may be configured such that, when the second contact portion interacts with the mating structure, the compliant beam is deflected such that the first contact portion contacts the first type conductor.

In some embodiments, each of the plurality of second type conductors may comprise a wire coupled to the contact of the second type conductor.

In some embodiments, the first type conductor may comprise a conductive pad configured to contact the first contact portions of the plurality of second type conductors when the compliant beams of the contacts of the plurality of second type conductors are deflected.

In some embodiments, the electrical connector may include a housing member holding the first type conductor and the plurality of second type conductors.

In some embodiments, the housing member may comprise a plurality of openings corresponding to the plurality of second type conductors such that each opening exposes, to the first type conductor, the first contact portion of one of the plurality of second type conductors.

In some embodiments, for each opening, a second contact portion of one of the plurality of second type conductors may curve out of the opening.

In some embodiments, the housing may comprise a base portion and a pair of walls extending from the base portion in a longitudinal direction and separated by a gap, the pair of walls each comprising first and second recesses facing the gap. The first type conductor may be coupled to one of the walls and separated from the gap by the wall. The electrical connector may comprise a pair of power conductors each disposed in a first recess of a respective one of the pair of walls and comprising a plurality of contact portions curving into the gap; and a pair of sense conductors each disposed in a second recess of a respective one of the pair of walls and comprising a contact portion curving into the gap and being offset from the plurality of contact portions of a respective power conductor along the longitudinal direction.

In some embodiments, the pair of sense conductors may each comprise a body portion disposed in the base portion of the housing, a beam extending from the body portion and disposed in the second recess of a respective one of the pair of walls, and a tail portion extending from the body portion and out of the base portion of the housing.

In some embodiments, for each of the pair of sense conductors, the body portion may have a C-shaped cross-section.

In some embodiments, for each of the pair of sense conductors, the body portion may comprise a member having a distal end configured to create interference with the base portion of the housing.

In some embodiments, the pair of power conductors may comprise a first power conductor and a second power conductor. The pair of sense conductors may comprise a first sense conductor having the contact portion spaced from the contact portion of the first power conductor by a first distance, and a second sense conductor having the contact portion spaced from the contact portion of the second power conductor by a second distance. The first distance may be less than the second distance.

In some embodiments, the wall holding the first sense conductor may comprise a plurality of third recesses separated from the first and second recesses of the wall by the wall. The electrical connector may comprise a ground conductor comprising a plurality of beams each disposed in one of the plurality of third recesses.

Some embodiments relate to electrical connector configured for mating with a mating structure. The electrical connector may include a connector housing; and a position identification subassembly coupled to the connector housing and comprising: a subassembly housing, a first type conductor coupled to the subassembly housing, and a plurality of second type conductors, each of the plurality of second type conductors comprising a first contact portion held by the subassembly housing adjacent the first type conductor and a second contact portion extending out of the subassembly housing.

In some embodiments, the connector housing may comprise a pair of walls separated by a gap. The connector may further comprise a plurality of conductors, each of the plurality of conductors comprising a contact portion extending into the gap. The position identification subassembly may be coupled to a wall of the pair of walls outside of the gap.

In some embodiments, the second contact portions of the plurality of second type conductors may be disposed in an array comprising a plurality of rows and a plurality of columns.

In some embodiments, the plurality of second type conductors may be arranged in pairs. For the second type conductors in each pair, the first contact portions and the second contact portions may be aligned in a row direction, with the pair of first type contact portions separating the pair of second type contact portions.

In some embodiments, the plurality of second type conductors may each comprise a mounting portion. The mounting portions of the plurality of second type conductors may be aligned in a column direction perpendicular to the row direction.

In some embodiments, the first type conductor may comprise a mounting portion aligned with the mounting portions of the plurality of second type conductors in the column direction.

In some embodiments, the first type conductor may comprise a conductive pad configured to contact the first contact portions of the plurality of second type conductors, and one or more portions joining the conductive pad and the mounting portion of the first type conductor.

Some embodiments relate to an electrical system. The electrical system may include an electrical connector described herein; a printed circuit board; a plurality of cables comprising first ends coupled to the electrical connector and second ends opposite to the first ends; and one or more lugs connecting the second ends of the plurality of cables to the printed circuit board.

In some embodiments, the one or more lugs may be locked to the printed circuit board.

In some embodiments, the plurality of cables may comprise a first group connected to a first power conductor of the electrical connector and a second group connected to a second power conductor of the electrical connector. The one or more lugs may comprise a first lug connecting the first group of the plurality of cables to the printed circuit board, and a second lug connecting the second group of the plurality of cables to the printed circuit board.

In some embodiments, the first lug may comprise a first bending arm inserted into a first hole of the printed circuit board. The second lug may comprise a second bending arm inserted into a second hole of the printed circuit board. The first bending arm of the first lug and the second bending arm of the second lug may extend toward opposite directions.

In some embodiments, the first lug may comprise a first contact portion surrounding the second ends of the first group of the plurality of cables, a first extension from the first contact portion, and the first bending arm extending from the first extension. The second lug may comprise a second contact portion surrounding the second ends of the second group of the plurality of cables, a second extension from the second contact portion, and the second bending arm extending from the second extension.

In some embodiments, the electrical system may include a first screw extending through the first extension of the first lug to the printed circuit board, and a second screw extending through the second extension of the second lug to the printed circuit board.

Some embodiments relate to a busbar assembly. The busbar assembly may include a busbar; and a shell comprising a recess and a first portion having a surface. The busbar may be disposed within the recess. The first portion may comprise a plurality of features configured in a plurality of unique patterns at each of a plurality of positions on the first portion of the shell.

In some embodiments, the plurality of features may comprise protrusions extending above the surface of the first portion.

In some embodiments, the plurality of features may comprise openings through the surface of the first portion.

In some embodiments, the surface of the first portion may be an insulative surface.

In some embodiments, the shell may comprise a second portion having a conductive surface extending in parallel to the insulative surface of the first portion.

In some embodiments, the busbar may comprise a base portion having a first thickness, a mating portion having a second thickness, and a transition portion extending between the base portion and the mating portion such that the second thickness is less than the first thickness.

In some embodiments, the insulative surface and the conductive surface may be separated from each other by a first distance greater than the second thickness. The shell may comprise additional surfaces separated from each other by a second distance greater than the first distance.

In some embodiments, the busbar may comprise a first blade having a first insertion edge, a second blade having a second insertion edge being offset from the first insertion edge along a second direction perpendicular to the first direction, and an insulating layer between the first and second blades.

Some embodiments relate to an electrical system. The electrical system may include a busbar assembly described herein; and a connector mated to the busbar, the connector comprising a plurality of position identification contact portions. One or more of the plurality of position identification contact portions may each curves into engagement with one of the plurality of features of the first portion of the shell of the busbar assembly.

Some embodiments relate to an electrical system. The electrical system may include a busbar assembly described herein; and a connector inserted on the busbar, the connector comprising a plurality of position identification contact portions. The insulative surface of the first portion of the shell of the busbar assembly may press against one or more of the plurality of position identification contact portions.

Some embodiments relate to an electrical system. The electrical system may include a busbar assembly described herein; a connector inserted on the busbar, the connector comprising: a housing comprising a base portion, a pair of walls extending from the base portion in a longitudinal direction and separated by a gap, and a pair of wings extending from the base portion in opposite directions perpendicular to the longitudinal direction, and a ground conductor extending from one of the pair of walls to a respective wing of the pair of wings, and comprising a plurality of first contact portions curving away from the wall and second contact portions curving away from the respective wing; and a power supply unit coupled to the busbar through the connector, the power supply unit comprising a printed circuit board and a shell enclosing the printed circuit board. The plurality of first contact portions of the ground conductor may contact the conductive surface of the shell of the busbar assembly. The plurality of second contact portions of the ground conductor may contact the shell of the power supply unit.

Some embodiments relate to a method of determining a position of a connector configured to mate to a busbar enclosed in a shell, the connector comprising a first type conductor and a plurality of second type conductors each comprising a contact portion. The method may include mating the connector to the busbar with the plurality of second type conductors adjacent the shell; for each of the plurality of second type conductors, detecting whether the contact portion of the second type conductor is electrically connected to the first type conductor; and indicating a position of the connector based on a pattern of the plurality of second type conductors electrically connected to the first type conductor.

In some embodiments, the method may further comprise prior to detecting whether the contact portions of the second type conductors are electrically connected to the first type conductor, determining that the connector is in a mating position by detecting an electrical connection between a sense contact and the busbar.

In some embodiments, the busbar may comprise unique codes at a plurality of positions on the busbar.

In some embodiments, the method may comprise determining the position of the connector inserted on the busbar by comparing the recognized signals for the plurality of second type conductors with the unique codes of the plurality of positions on the busbar.

In some embodiments, the method may comprise determining the connector being inserted at the position of the plurality of positions on the busbar when the recognized signals for the plurality of second type conductors equal to the unique code assigned to the position.

In some embodiments, the pattern of the plurality of second type conductors may correspond to relative positions among the plurality of second type conductors.

In some embodiments, encoding the pattern of the plurality of second type conductors electrically connected to the first type conductor as the indicator of the position of the connector may comprise, for each of the plurality of second type conductors: recognizing a digital “1” signal when the contact portion of the second type conductor is not electrically connected to the first type conductor, and recognizing a digital “0” signal when the contact portion of the second type conductor is electrically connected to the first type conductor.

In some embodiments, encoding the pattern of the plurality of second type conductors electrically connected to the first type conductor as the indicator of the position of the connector may comprise, for each of the plurality of second type conductors: recognizing a digital “0” signal when the contact portion of the second type conductor is not electrically connected to the first type conductor, and recognizing a digital “1” signal when the contact portion of the second type conductor is electrically connected to the first type conductor.

Some embodiments relate to an electronic system. The electronic system may include a subassembly; a support structure comprising a plurality of positions, each of the plurality of positions configured to receive a subassembly; and a controller. The subassembly may be installed in the support structure at a position of the plurality of positions. The subassembly may be configured to interact with the support structure at the position of the plurality of positions and generate an indication of the position of the plurality of positions in which the subassembly is installed. The subassembly may be configured to communicate status and/or control information with the controller, the status and/or control information being associated with position information generated based on the indication of the position.

In some embodiments, the subassembly may comprise an electrical connector. Each position of the support structure may comprise a mating component configured to mate with the electrical connector. The electrical connector may be configured to output the indication of the position.

In some embodiments, the support structure may comprise a busbar. The electrical connector may be a power connector configured to mate with the busbar.

In some embodiments, the subassembly may be a power supply unit. The power supply unit may be configured to report, to the controller, a status of the power supply unit in conjunction with an identified position of the power supply unit.

In some embodiments, the controller may be configured to generate commands to the power supply unit based on the identified position.

In some embodiments, the commands to the power supply unit based on the identified position may be based on a voltage drop between a voltage source and the position.

In some embodiments, the commands to the power supply unit based on the identified position may be based on a length of a conducting path between the position and a load.

In some embodiments, the power supply unit may be configured to determine whether a position code carried by the commands matches the position code generated by the power supply unit; when it is determined that the position codes do not match, ignore the commands received from the controller; and when it is determined that the position codes match, execute the commands received from the controller.

In some embodiments, the electronic system may further comprise a user interface. The controller may be configured to present on the user interface the status information for the subassembly based on the position information generated based on the indication of the position.

In some embodiments, the controller may be configured to identify a subassembly in a fault state and display on the user interface an indication of the subassembly with the fault and a position of the subassembly.

In some embodiments, the support structure may comprise a cooling tank. The plurality of positions may be within the cooling tank.

In some embodiments, the subassembly may be a first subassembly. The electronic system may comprise a plurality of subassemblies, including the first subassembly. Each of the plurality of subassemblies may be configured like the first subassembly to interact with the support structure at a position of the plurality of positions and generate an indication of the position of the plurality of positions in which the subassembly is installed.

In some embodiments, the plurality of subassemblies may be power supplies.

In some embodiments, the plurality of subassemblies may be servers.

In some embodiments, the support structure may comprise a rack. The plurality of positions may be slots within the rack.

In some embodiments, the controller may be remote from the support structure. The electronic system may comprise a network connecting the controller to the subassembly.

Some embodiments relate to an electronic system. The electronic system may include a power supply unit configured to: generate a position code based on a position within the electronic system in which the power supply unit is installed, generate status information, and transmit the status information associated with the position code; and a controller comprising a non-transitory computer readable storage medium comprising computer executable instructions configured to, when executed: receive, from the power supply unit, the position code and the status information, process the status information to generate a result, and associate the result with a position within the electronic system.

In some embodiments, the power supply unit may be a first power supply unit. The system may comprise a plurality of power supply units, including the first power supply unit. Processing the status information to generate the result may comprise reporting the status of the first power supply unit differentiated from others of the plurality of power supply units based on the position code.

In some embodiments, the power supply unit may be a first power supply unit. The electronic system may comprise a plurality of power supply units, including the first power supply unit. The controller may be configured to communicate with the plurality of power supply units. The first power supply unit may be configured to: receive commands from the controller, determine whether a position code carried by the received commands matches the position code generated by the first power supply unit, when it is determined that the position codes do not match, ignore the received commands, and when it is determined that the position codes match, execute the received commands.

In some embodiments, the electronic system may further comprise a user interface coupled to the controller. The computer executable instructions may be further configured to, when the result indicates a fault of the power supply unit, present the result on the user interface in connection with a position of the power supply unit.

In some embodiments, the controller may be within the power supply unit.

Some embodiments relate to an electronic system. The electronic system may include a busbar; a plurality of connectors mated to the busbar, each of the plurality of connectors configured to provide one or more signals indicating a position of the connector on the busbar; a user interface; and a controller configured to provide on the user interface status information indicating status within the electronic system in combination with information indicating a position within the system of the status, wherein the controller is configured to generate the information indicating the position based on the one or more signals indicating the position on the busbar of at least one connector of the plurality of connectors.

In some embodiments, each of the plurality of connectors may be configured to provide a status of a connection between the connector and the busbar. The statuses of the connections between individual connectors and the busbar may be provided to the user interface.

In some embodiments, the controller may be configured to execute computer executable instructions to: receive, from each of the plurality of connectors, the one or more signals indicating the position of the connector on the busbar, compute the positions of the plurality of connectors on the busbar based on the received signals, and provide the positions of the plurality of connector on the busbar to the user interface.

In some embodiments, each of the plurality of connectors may be associated with a respective subassembly of a plurality of subassemblies. The status information may comprise status information of the subassembly.

In some embodiments, the status information may comprise an indication of a fault within a subassembly of the plurality of subassemblies.

These techniques may be used alone or in any suitable combination. The foregoing summary is provided by way of illustration and is not intended to be limiting.

### BRIEF DESCRIPTION OF DRAWINGS

Various aspects and embodiments of the present disclosure are described below with reference to the accompanying drawings. The drawings are not necessarily drawn to scale. Each identical or nearly identical component that is illustrated in various drawings may be represented by a like numeral. For the purposes of clarity, not every component may be labeled in every drawing. In the drawings:

FIG. 1A is a schematic perspective view of an electrical system comprising connectors that connect power supply units (PSUs) to a busbar assembly, according to some embodiments.

FIG. 1B is a cross-sectional schematic perspective view of the electrical system of FIG. 1A along the line marked “1B-1B” in FIG. 1A.

FIG. 2A is a perspective view of a part of the electrical system of FIG. 1A, illustrating a connector connected to a printed circuit board (PCB) via cables, according to some embodiments.

FIG. 2B is another perspective view of the electrical system of FIG. 2A.

FIG. 2C is a perspective view of a lug of the electrical system of FIG. 2A.

FIG. 3A is a perspective view of a connector of FIG. 1A, showing a side with a position identification subassembly.

FIG. 3B is a perspective view of the connector of FIG. 3A, showing a side with a ground conductor.

FIG. 3C is a rear perspective view of the connector of FIG. 3A.

FIG. 3D is a cross-sectional perspective view of the connector of FIG. 3A along the line marked “3D-3D” in FIG. 3C.

FIG. 4 is a perspective view of the connector of FIG. 3A, with a housing hidden.

FIG. 5 is a perspective view of a pair of power conductors of the connector of FIG. 3A.

FIG. 6A is a rear perspective view of the connector of FIG. 3A, showing the housing holding the pair of power conductors of FIG. 5 and positioning blocks, with other components hidden.

FIG. 6B is a perspective view of a positioning block of FIG. 6A.

FIG. 6C is a bottom perspective view of the connector of FIG. 6A.

FIG. 7 is a perspective view of a pair of sense conductors of the connector of FIG. 3A.

FIG. 8A is a top perspective view of the position identification subassembly of the connector of FIG. 3A.

FIG. 8B is a bottom perspective view of the position identification subassembly of FIG. 8A.

FIG. 8C is a perspective view of position identification conductors of the position identification subassembly of FIG. 8A.

FIG. 8D is a perspective view of a loop conductor of the position identification subassembly of FIG. 8A.

FIG. 8E is a top perspective view of a housing member of the position identification subassembly of FIG. 8A.

FIG. 8F is a bottom perspective view of the housing member of FIG. 8B.

FIG. 9 is a perspective view of a ground conductor of the connector of FIG. 3A.

FIG. 10 is a block diagram of an electronic system that may be implemented using connectors with position encoding, according to some embodiments.

FIG. 11 is a flow chart illustrating a method of determining a position of a connector on a mating structure, according to some embodiments.

FIG. 12 is a schematic diagram illustrating a tank of a data center that may be implemented using connectors with position encoding, according to some embodiments.

FIG. 13 is a block diagram of a machine in the form of a computer that can find application in the system(s) disclosed herein, according to some embodiments.

### DETAILED DESCRIPTION

The Inventors have recognized and appreciated designs that facilitate maintenance and/or control of electronic systems. Subassemblies of a system may be configured to generate position information indicating a position within the system of the subassembly. This position information may be associated with status messages from the subassembly or commands to the subassembly. Conversely, the position information may be associated with commands or control information directed to a specific subassembly of multiple like subassemblies.

The position information may be generated by a connector, such as a power connector, that couples the subassembly to a source of power. Circuitry within the subassembly may tag status information from the subassembly with the position information. Status information, such as information indicating a fault may be communicated to a technician, and may enable the technician to quickly identify a subassembly that requires service. Such a capability may significantly enhance efficiency in a system with a large number of subassemblies of the same type.

For example, a server farm may contain support structures, such as racks or cooling tanks, that contain multiple, identical power supplies. Were one power supply to experience a fault, even when the power supply sends status information to a stem controller indicating that a fault occurred, finding the faulty power supply from among the many power supplies could require a time-consuming search for the faulty power supply. That search can be avoided if the status information is presented to a maintenance technician along with position information. The capability would be particularly valuable for subassemblies that are not readily observable, such as for power supplies that are in a cooling tank.

With designs as described herein, the position information may be generated by a power connector, which may be used in power supplies or other subassemblies. In some embodiments, the connector may be a multifunction connector.

A multifunction connector may have multiple position identification contacts, each of which may be positioned to selectively interact with a mating structure where the connector is mated to that structure. Interaction with the mating structure may activate a position identification contact. For a busbar connector, the position identification contacts may be positioned to interact with a shell of a busbar, for example.

The mating structure may be configured differently at each of multiple mating positions for a multifunction connector such that a different combination of position identification contacts is activated depending on the mating position of a specific connector. In an electronic system assembled with multiple connectors, different ones of the connectors, even though having the same structure, may have a different pattern of activated and un-activated position identification contacts, depending on the mating position of the connector within the system.

A PSU or other subassembly to which the connector is connected may sense the state of each of the plurality of position identification contacts. By encoding the pattern of activated and un-activated states of the position identification contacts for a connector, a PSU or other subassembly including the multifunction connector may generate a code indicating its position within the electronic system. A PSU or other subassembly using the multifunction connector may provide the code in connection with status reports or other outputs. As a result, a system controller may determine and report status of particular subassemblies based on position within the system. Likewise, the controller may generate commands to subassemblies based on position within the system. For example, in an electronic system with subassemblies inserted into a rack, each slot in the rack may be associated with a different pattern of activated and un-activated position sense contacts and each of multiple PSUs may report its status based on slot and respond to commands directed to a particular slot. Such a capability may enable more robust determination of system status and control.

The position identification contacts may be constructed to enable a simple and compact connector construction. For example, the position identification contacts may be manufactured as a position identification subassembly which may be attached to a connector housing. The position identification subassembly may include a first type conductor, an example of which is a loop conductor as described herein, and multiple second type conductors, an example of which are the position identification conductors described herein. The loop conductor may have, for example, a wire terminated at one end with a conductive pad. Each of the position identification conductors may have a position identification contact which may be configured as a complaint beam, for example. The compliant beam may have a first contact portion and a second contact portion. The first contact portion may be configured to contact the loop conductor when the connector is inserted into a mating structure and the second contact portion engages with the mating structure, thereby deflecting the beam when the position identification conductor is activated.

An activated state of a position identification conductor may be detected by measuring a current flow through the loop conductor to the position identification conductor or a voltage level at the loop conductor being coupled to the position identification conductor. The presence or absence of such an electrical coupling may represent an output of the position identification conductors. These outputs may be digitized. In some embodiments, a digital “1” signal may be recognized when a position identification conductor contacts the loop conductor; and a “0” signal may be recognized when a position identification conductor does not contact the loop conductor.

The position identification conductors may include wires terminated at one end by position identification contacts. The wires may be routed to a PSU or other subassembly into which the position identification subassembly is integrated. The loop conductor may similarly be coupled to the PSU.

The multifunction connector may be configured as a busbar connector, which may mate with a busbar assembly that may have multiple positions configured for receiving connectors. Such a busbar assembly may have a shell made from, coated with or otherwise incorporating insulative material. The position identification contacts may selectively interact with the shell of the busbar by pressing against an insulative portion of the shell. The position identification contacts may be un-activated where they fit within an opening in the busbar shell.

The portions of the shell corresponding to the positions for mating with a busbar connector may include openings disposed according to different codes. Each position may be assigned a unique code. The position identification contacts for each of the position identification conductors may have a second contact portion configured for contacting the shell for the busbar, if no opening is present. When the second contact portions contact the shell, corresponding first contact portions move accordingly until contacting the loop conductor. The shell for the busbar may have openings, into which second contact portions can extend and therefore stay in their rest states without the first contact portions corresponding to those second contact portions being pressed into contact the loop conductor. Such a configuration enables the determination of the positions of the connectors inserted on the busbar by comparing the outputs of the position identification conductors with the unique codes assigned to the positions. It may be determined that a connector is inserted at a position along the busbar when the outputs of the connector's position identification conductors equal to the code of the position.

A multifunction connector may have sense conductors configured for providing information about the degree of insertion on a busbar. The sense conductors may be disposed such that, when the connector is being inserted on the busbar, the sense conductors contact the busbar after power conductors of the connector contact the busbar; and when the connector is being removed from the busbar, the sense conductors disconnect from the busbar before the power conductors disconnect from the busbar. The outputs of the sense conductors may be used to determine when to power on and off the busbar and/or the system such that hot plug may be avoided and therefore reduce the possibility of damaging the connector. The outputs of the sense conductors may be used to determine when to read the outputs of the position identification conductors. If the connector is not properly mated, the position code will not be accurate.

A multifunction connector may have a ground conductor configured for connecting the shell for the busbar to a shell of a PSU that is connected to the busbar through the connector. Such a configuration provides improved grounding protection.

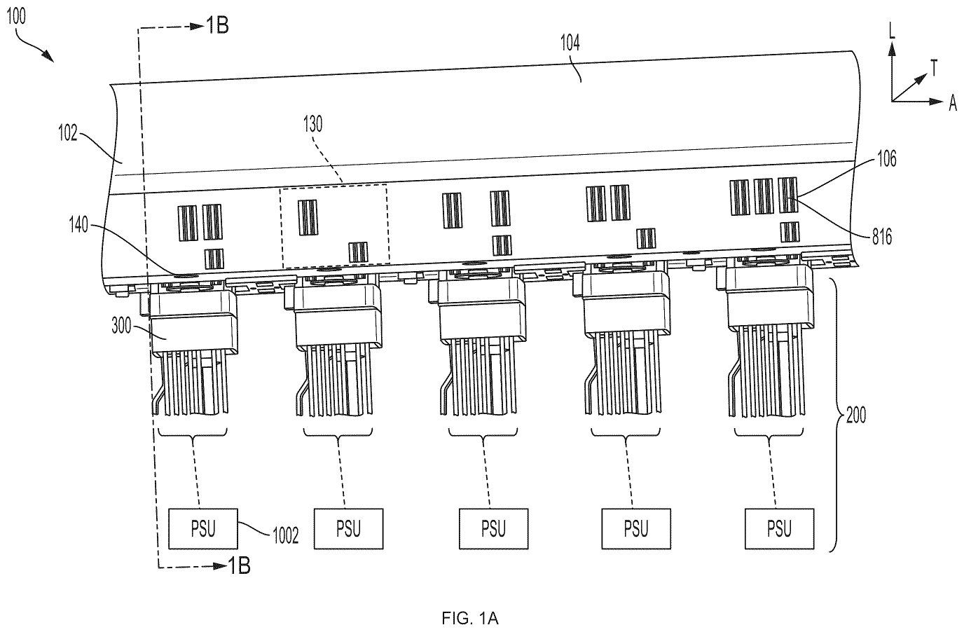

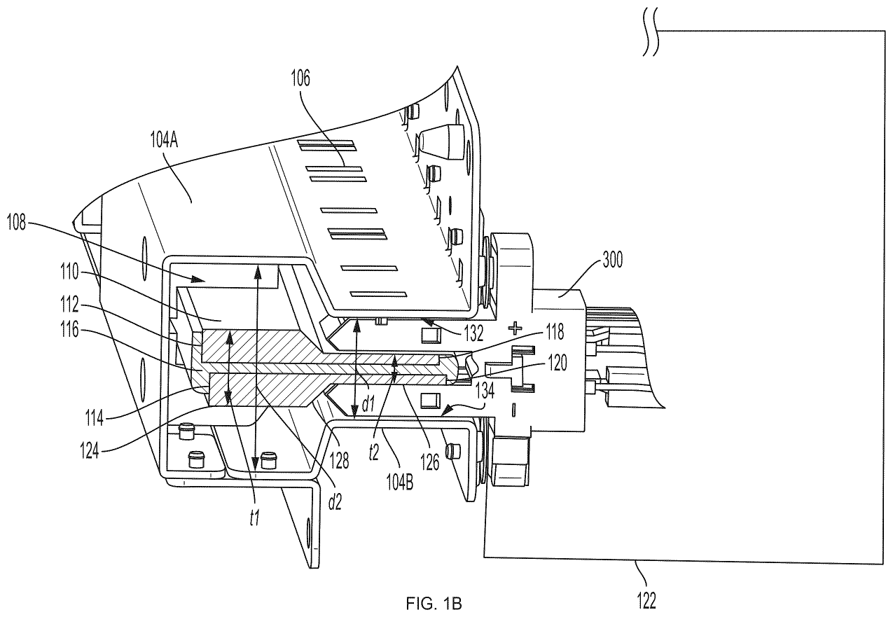

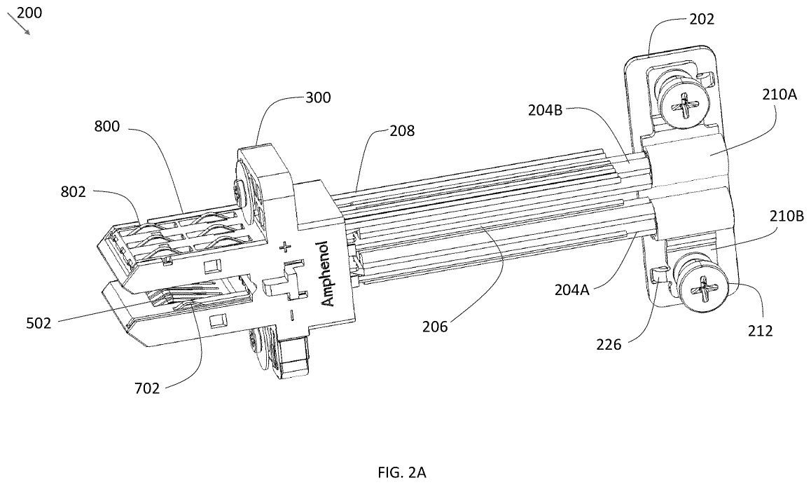

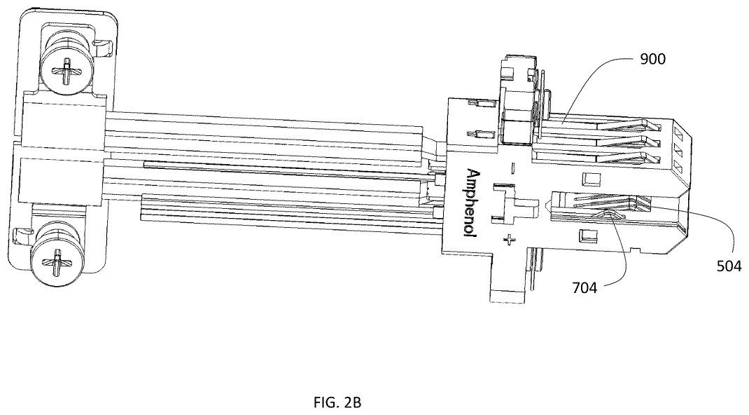

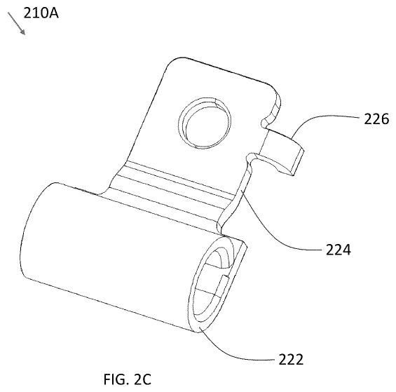

FIGS. 1A-2B are an example of techniques as described herein integrated into an electrical system 100. The electrical system 100 may include a busbar assembly 102, power supply units (PSUs) 1002, and multifunction connectors 300 mated to the busbar assembly 102 and each connecting one of the PSUs 1002 to the busbar assembly 102.

The busbar assembly 102 may be configured with features to interact with the connectors 300 so as to provide functions in addition to simple electrical interconnection. As illustrated, the busbar assembly 102 includes a shell 104 having a recess 108, and a busbar 110 disposed in the recess 108. The busbar 110 may include a base portion 124 having a first thickness t1, a mating portion 126 having a second thickness t2, and a transition portion 128 extending between the base portion 124 and the mating portion 126 such that the second thickness t2 is less than the first thickness t1. The busbar 110 may include a first blade 112 having a first insertion edge 118, a second blade 114 having a second insertion edge 120, and an insulation layer 116 between the first and second blades 112 and 114. The first insertion edge 118 may be offset from the second insertion edge 120. As a specific example, the offset may be on the order of 2 mm to 5 mm. Such a configuration may be used, for example, in a busbar in which the first blade 112 is connected to a supply line of a circuit of the power supply and the second blade 114 is connected to a return line for that circuit, such that a connector mates with the return line before the supply line when the connector is being mated to the busbar.

The shell 104 may include a first portion 104A having an insulative surface 132, and a second portion 104B having a conductive surface 134. The insulative surface 132 and conductive surface 134 may extend substantially in parallel to each other. The insulative surface 132 and conductive surface 134 may be separated from each other by a first distance d1. The first distance d1 may be sized such that the insulative surface 132 can interact with position identification conductors 802 of the connector 300 and the conductive surface 134 can be coupled to a PSU shell 122 via a ground conductor 900 of the connector 300. The shell 104 may include additional surfaces separated from each other by a second distance d2 that is greater than the first distance d1.

The busbar assembly 102 may have multiple positions 140 each configured for receiving a connector. The first portion 104A of the shell 104 of the busbar assembly 102 may have openings 106 at each position 140. The openings 106 at each position 140 may be configured in a unique pattern 130 such that connectors mated with the busbar 110 at different positions, even though having the same structure, may have a different pattern of the states of the position identification conductors 802. The state of a position identification conductor 802 may depend on a state of a second contact portion 816 of the position identification conductor 802 such as being pressed by the insulative surface 132 or resting in an opening 106.

Accuracy with which the position of a connector is identified may be improved if the position of the connector is identified after the connector is mated to the busbar at a desired degree. As illustrated, the connector 300 may include sense conductors 702 and 704 configured for providing information about the degree of insertion of the connector 300 on the busbar 110. The outputs of the sense conductors 702 and 704 may be used to determine when to read the outputs of the position identification conductors 802. Alternatively or additionally, the configuration of the busbar assembly 102 including, for example, the transition portions 128 of the busbar 110 and the size of the first distance d1 between the insulative surface 132 and conductive surface 134, may prevent an over-insertion of the connector 300.

Cables may be used to distribute power and transmit signals in the electrical system 100. FIGS. 2A-2B are perspective views of a part 200 of the electrical system 100. As illustrated, power conductors 502 and 504 of the connector 300 may be coupled to a printed circuit board (PCB) 202 of the PSU 1002 via groups of cables 204A, 204B, respectively. The group of cables 204A may have first ends coupled to the power conductor 502, and second ends coupled to the PCB 202 via a lug 210A. Similarly, the group of cables 204B may have first ends coupled to the power conductor 504, and second ends coupled to the PCB 202 via a lug 210B. The lugs 210A and 210B may be configured such that they can be locked to the PCB 202 to ensure stable and reliable interconnection between the groups of cables 204A and 204B and the PCB 202. As illustrated, the lug 210A may include a contact portion 222, an extension 224 extending from the contact portion 222, and a bending arm 226 extending from the extension 224 and inserted into a hole of the PCB 202. The contact portion 222 may substantially surround the second ends of the cables 204A. The lug 210B may be configured similar to the lug 210A. Each lug and the PCB 202 may have matching holes for a screw 212 extending through. The configuration with the lugs and groups of cables, as compared to a single cable for each power conductor, may enable at least ±3 mm floating and therefore good flexibility in a tight space in the system while providing stable and reliable interconnection. The system 200 may include additional cables such as one or more cables 206 and one or more cables 208 for coupling the sense conductors 702 and 704 and the position identification conductors 802 to the PCB 202 or another part of the PSU 1002 or another component in the system.

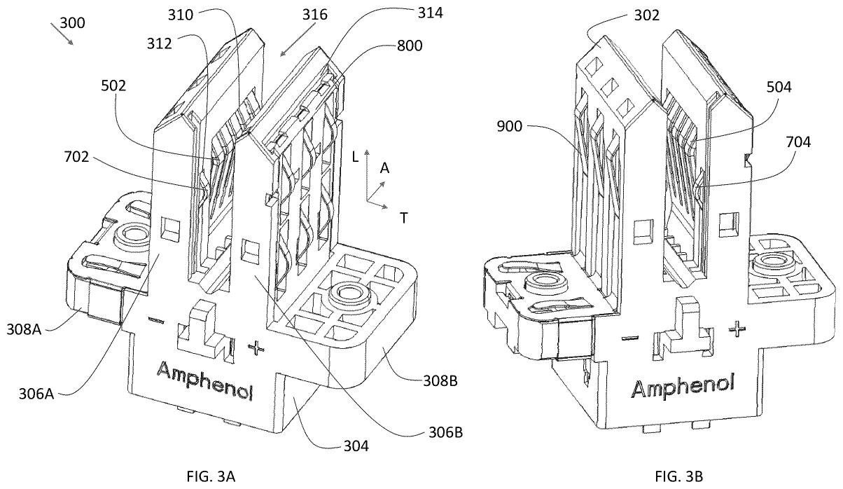

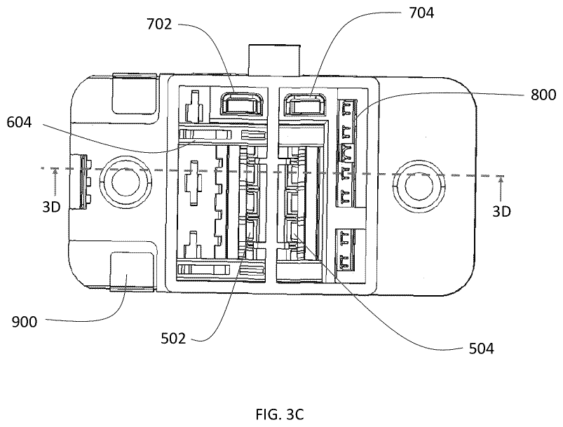

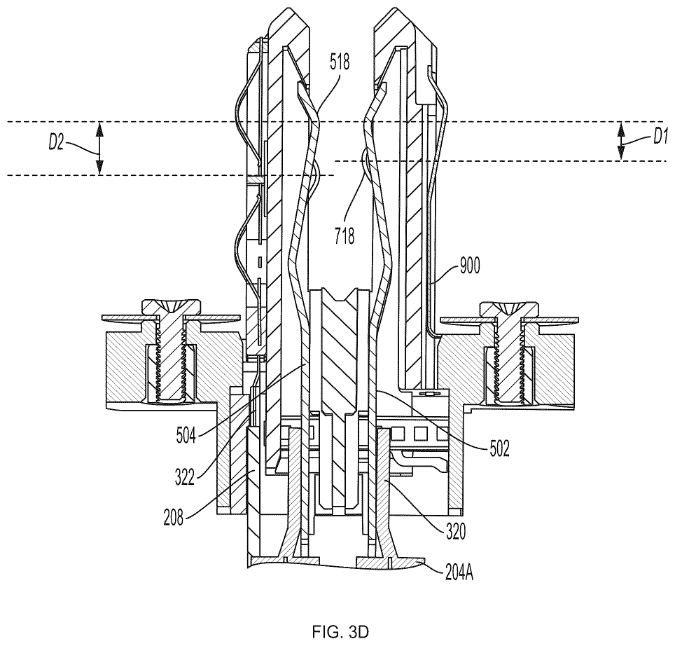

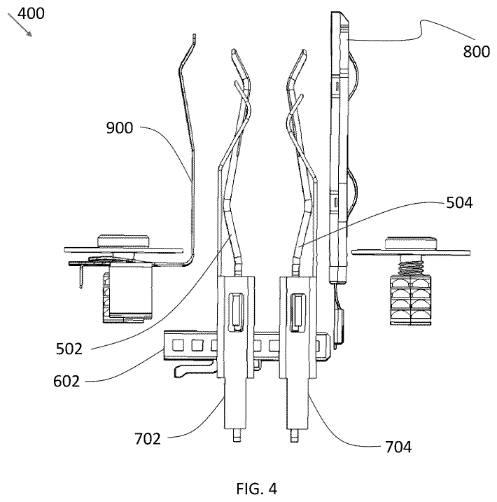

FIGS. 3A-9 illustrate an embodiment of the connector 300. The connector 300 may include a housing 302 having a base portion 304, a pair of walls 306A and 306B extending from the base portion 304 in a longitudinal direction L (sometimes referred to as the “mating direction”) and separated by a gap 316, and a pair of wings 308A and 308B extending from the base portion 304 in opposite directions perpendicular to the longitudinal direction L. The pair of walls 306A and 306B may each include recesses facing the gap 316 such as a first recess 310 and a second recess 312, and one or more recesses separated from the gap by the respective wall such as a third recess 314.

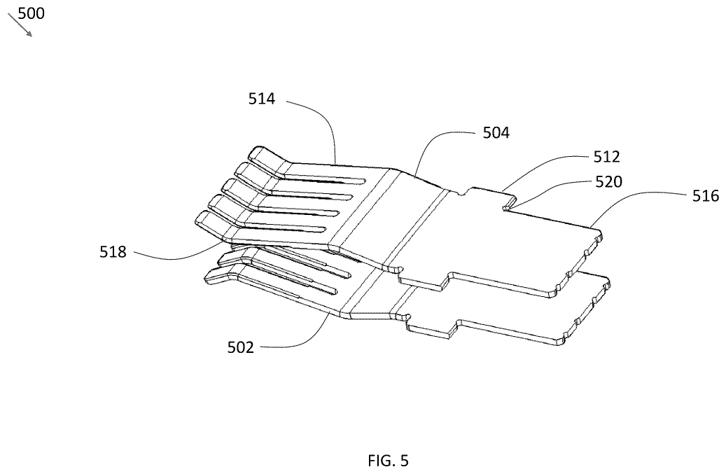

As shown in FIG. 5, the power conductors 502 and 504 may each include a portion 512 configured to be fixedly held in the housing 302, contact fingers 514 extending from the portion 512 and disposed in one first recess 310 so as to flex when the connector is being mated, and a mounting portion 516 that may be coupled to the first ends of one of the groups of cables 204A and 204B. FIG. 3D shows that the mounting portion 516 of the power conductor 502 is coupled to a wire 320 of the group of cables 204A. Each contact finger 514 may include a contact portion 518 configured to curve into the gap 316 between the pair of walls 306A and 306B.

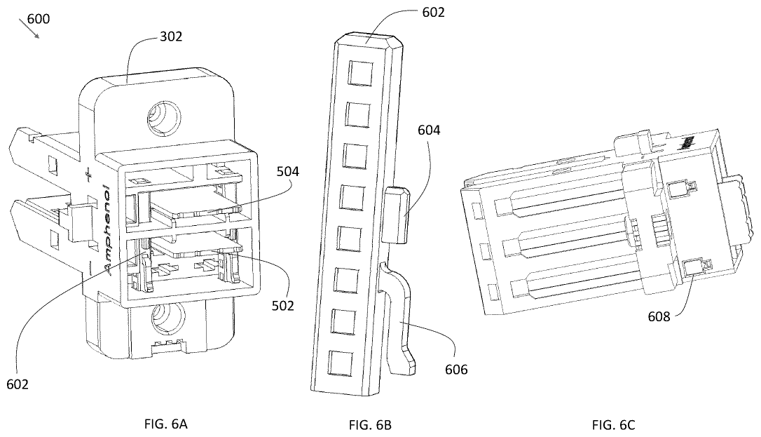

As shown in FIGS. 6A-6C, the connector 300 may include a pair of positioning block 602 configured to prevent the power conductors 502 from moving in the mating direction under the force generated while mating the connector 300. The housing 302 may include openings 608 to receive ends of the positioning blocks 602 such that the position blocks 602 are disposed at the joints 520 between the portion 512 and the mounting portion 516 of the power conductors 502 and 504. Each positioning block 602 may include a projection 604 and a leg 606 configured to prevent the positioning block 602 from moving in a direction perpendicular to the mating direction.

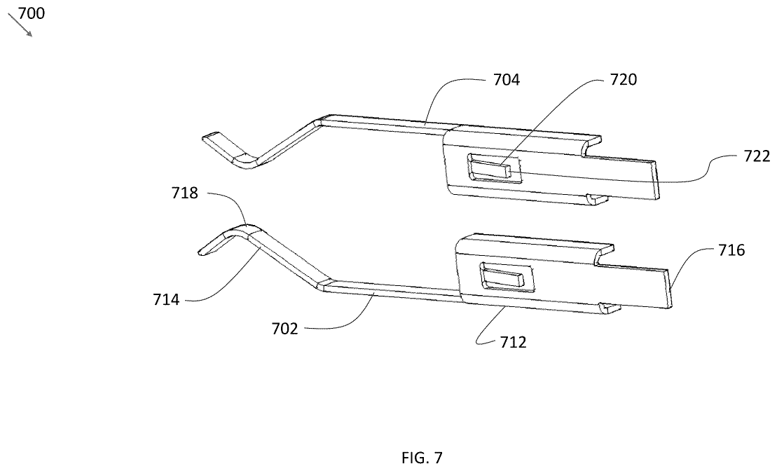

As shown in FIG. 7, the sense conductors 702 and 704 may each include a body portion 712 disposed in the base portion 304 of the housing 302, a beam 714 extending from the body portion 712 and disposed in one second recess 312 so as to flex when the connector is being mated, and a tail 716 extending from the body portion 712 and opposite to the beam 714. The body portion 712 may include a member 720 having a distal end 722 to create interference with the base portion 304 of the housing 302. As illustrated, the body portion 712 may have a C-shaped cross-section that may fit in a slot of the housing 302 (FIG. 3C). As shown in FIG. 3D, each beam 714 may include a contact portion 718 configured to curve into the gap 316 between the pair of walls 306A and 306B. The contact portion 718 of the sense conductor 702 may be offset from the contact portion 518 of the power conductor 502 by a distance D1. The contact portion 718 of the sense conductor 704 may be offset from the contact portion 518 of the power conductor 504 by a distance D2 that may be greater than the distance D1. Such a configuration may be used, for example, when the power conductor 504 is configured to mate to the busbar's first blade 112 that is connected to the supply line and the power conductor 502 is configured to mate to the busbar's second blade 114 that is connected to the return line, such that the connection to the return line is detected before the connection to the supply line when the connector is being mated to the busbar, and the disconnection from the supply line is detected before the disconnection from the return line when the connector is being removed from the busbar.

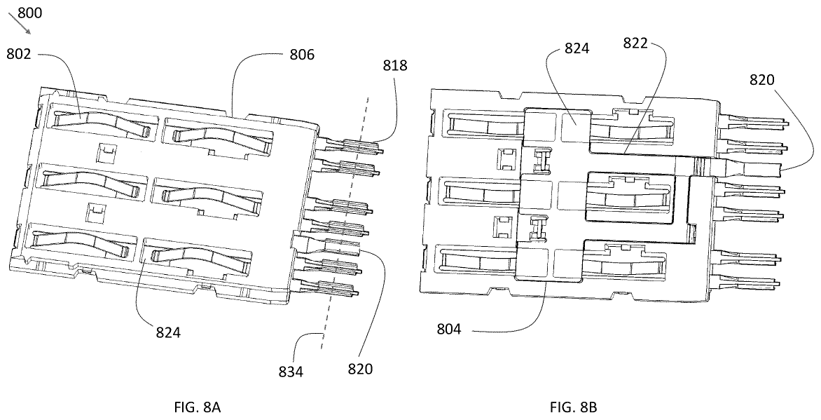

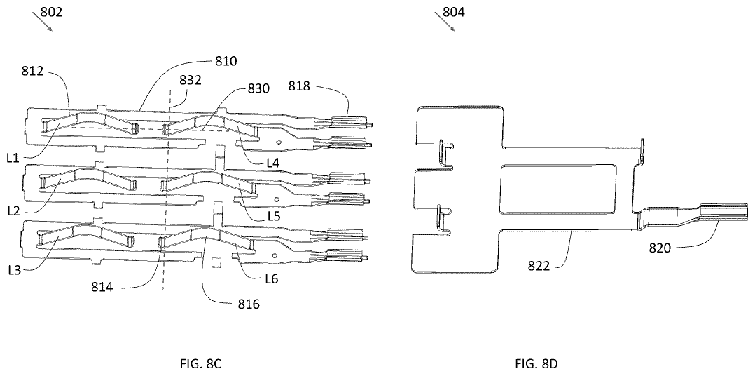

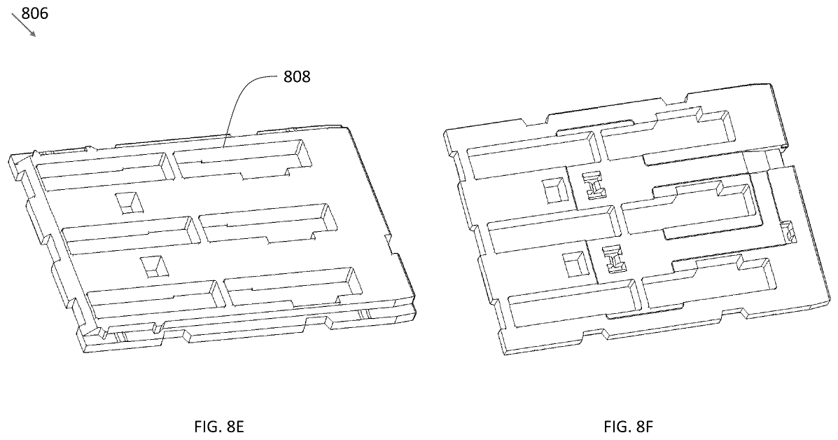

The position identification contacts may be configured to synergistically provide the function of position identification while satisfying the dimension requirements limited by the system. As shown in FIGS. 8A-8F, the connector 300 may include a position identification assembly 800, which may be disposed in the third recess 314 of the housing 302. The position identification assembly 800 may include the position identification conductors 802, a loop conductor 804 shared by the position identification conductors 802, and a subassembly housing 806 holding the position identification conductors 802 and loop conductor 804.

Each position identification conductor 802 may include a compliant beam 812 having a first contact portion 814 configured to make contact with the loop conductor 804 when a respective second contact portion 816 is pressed by a mating structure such as the insulative surface 132 of the busbar assembly 102. The first contact portions 814 may be disposed in an array comprising rows 830 and columns 832. The loop conductor 804 may include conductive pads 824 each configured to make contact with the first contact portion 814 of a respective position identification conductor 802. The subassembly housing 806 may include openings 808 each for exposing the first contact portion 814 of a respective position identification conductor 802 to a respective conductive pad 824 of the loop conductor 804. The respective second contact portion 816 may curve out of the opening 808 and away from the loop conductor 804. Each of the position identification conductor 802 may have a mounting portion 818 aligned in a column direction 834. The loop conductor 804 may have a mounting portion 820 aligned with the mounting portions 818 of the position identification conductor 802 in the column direction 834. The mounting portions 818 and 820 may be configured to contact a wire from multiple directions so as to provide stable and reliable interconnection while providing a high density configuration. In the illustrated example, each mounting portion is shaped as a cup to partially surround a wire. The loop conductor 804 may have one or more portions joining the conductive pads 824 and the mounting portion 820 such that the position identification conductors 802 can share one loop conductor 804.

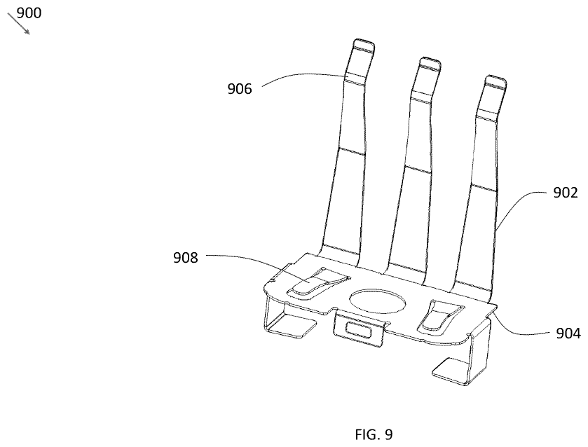

As shown in FIG. 9, the ground conductor 900 may include a body portion 904 disposed above the wing 308A of the housing 302, and beams 902 extending from the body portion 904 and each disposed in one of the third recess 314 of the wall 306A. Each beam 902 may have a first contact portion 906 configured to contact the conductive surface 134 of the shell 104 of the busbar assembly 102. The body portion 904 may have second contact portions 908 configured to contact the PSU shell 122 (see FIG. 1B). Connecting the shells of the busbar assembly and the PSU shell provides improved grounding protection.

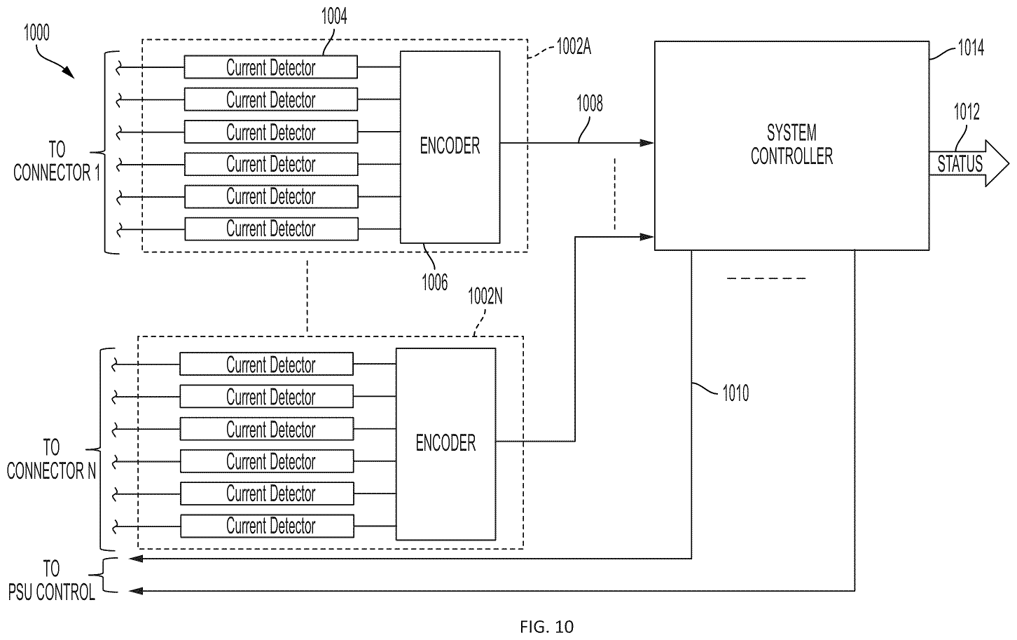

FIG. 10 shows a block diagram of an electronic system 1000 that may be implemented using connectors with position encoding, such as the connector 300. The electronic system 1000 may include a plurality of PSUs 1002A—1002N, which may be coupled to a mating structure via respective connectors 1-N. The PSUs 1002A—1002N may also be coupled to a system controller 1014 via any suitable approaches, such as cables, connectors, and/or a network. Each PSU may include a plurality of detectors, each coupled to one of the plurality of position identification conductor of a respective connector (for example, via cables 208 shown in FIG. 2A). The detectors may output a signal indicating whether the position identification conductor has been activated. The detector, for example, may be a current detector that detects a current flow through the conductor and/or may be a voltage detector. Optionally, the outputs of the detectors may be provided to an encoder 1006 configured to receive and encode the outputs of the detectors. In this example, each current detector 1004 may be configured to detect the state of the respective position identification conductor of the respective connector, such as whether the respective position identification conductor is electrically connected to the corresponding loop conductor. Although the illustrated example shows current detectors are used to detect the states of the position identification conductors, it should be appreciated that any suitable device and/or method may be used to detect the states of the position identification conductors. For example, voltage detectors may be used alternatively or in addition to the current detectors.

Each PSU may generate an output 1008, which may represent a pattern of the position identification conductors that may indicate a position of the connector. Referring back to FIG. 8C, the position identification conductors 802 may be identifiable by unique names such as L1-L6 depending on, for example, the disposition of their first contact portion 814 in the array having the rows 830 and columns 832. As described above, a digital “1” signal may be recognized when a position identification conductor contacts the loop conductor; and a “0” signal may be recognized when a position identification conductor does not contact the loop conductor. Accordingly, as shown in Table I below, the position identification conductors 802 may output fifty-four different combinations of 6-digit position codes depending on the states of the position identification conductors 802. Each position code may indicate a unique position on the mating structure (e.g., positions 140 on the busbar 110).

In some embodiments, the output 1008 of each PSU may include a status of the PSU, to which may be appended an identified position. In some embodiments, the status may indicate whether the PSU is operating as expected or having some problems. In some embodiments, the output 1008 of each PSU may include only the position code, and the system controller 1014 may process the position code and generate a status 1012 of the PSU that may include an identified position. It should be appreciated that Table I is provided as an example, and not intended to be limiting. The position codes and status may be represented in any suitable ways. For example, a digital “0” signal may be recognized when a position identification conductor contacts the loop conductor; and a “1” signal may be recognized when a position identification conductor does not contact the loop conductor.

TABLE I
An Example of Position Codes according to Encoded States of the
Position Identification Conductors
U POSITION PIN DEFINITION

| U | | | | | | |
|---|---|---|---|---|---|---|
| POSITION | L1 | L2 | L3 | L4 | L5 | L6 |
| 1 | 1 | 0 | 0 | 0 | 0 | 0 |
| 2 | 0 | 1 | 0 | 0 | 0 | 0 |
| 3 | 1 | 1 | 0 | 0 | 0 | 0 |
| 4 | 0 | 0 | 1 | 0 | 0 | 0 |
| 5 | 1 | 0 | 1 | 0 | 0 | 0 |
| 6 | 0 | 1 | 1 | 0 | 0 | 0 |
| 7 | 1 | 1 | 1 | 0 | 0 | 0 |
| 8 | 0 | 0 | 0 | 1 | 0 | 0 |
| 9 | 1 | 0 | 0 | 1 | 0 | 0 |
| 10 | 0 | 1 | 0 | 1 | 0 | 0 |
| 11 | 1 | 1 | 0 | 1 | 0 | 0 |
| 12 | 0 | 0 | 1 | 1 | 0 | 0 |
| 13 | 1 | 0 | 1 | 1 | 0 | 0 |
| 14 | 0 | 1 | 1 | 1 | 0 | 0 |
| 15 | 1 | 1 | 1 | 1 | 0 | 0 |
| 16 | 0 | 0 | 0 | 0 | 1 | 0 |
| 17 | 1 | 0 | 0 | 0 | 1 | 0 |
| 18 | 0 | 1 | 0 | 0 | 1 | 0 |
| 19 | 1 | 1 | 0 | 0 | 1 | 0 |
| 20 | 0 | 0 | 1 | 0 | 1 | 0 |
| 21 | 1 | 0 | 1 | 0 | 1 | 0 |
| 22 | 0 | 1 | 1 | 0 | 1 | 0 |
| 23 | 1 | 1 | 1 | 0 | 1 | 0 |
| 24 | 0 | 0 | 0 | 1 | 1 | 0 |
| 25 | 1 | 0 | 0 | 1 | 1 | 0 |
| 26 | 0 | 1 | 0 | 1 | 1 | 0 |
| 27 | 1 | 1 | 0 | 1 | 1 | 0 |
| 28 | 0 | 0 | 1 | 1 | 1 | 0 |
| 29 | 1 | 0 | 1 | 1 | 1 | 0 |
| 30 | 0 | 1 | 1 | 1 | 1 | 0 |
| 31 | 1 | 1 | 1 | 1 | 1 | 0 |
| 32 | 0 | 0 | 0 | 0 | 0 | 1 |
| 33 | 1 | 0 | 0 | 0 | 0 | 1 |
| 34 | 0 | 1 | 0 | 0 | 0 | 1 |
| 35 | 1 | 1 | 0 | 0 | 0 | 1 |
| 36 | 0 | 0 | 1 | 0 | 0 | 1 |
| 37 | 1 | 0 | 1 | 0 | 0 | 1 |
| 38 | 0 | 1 | 1 | 0 | 0 | 1 |
| 39 | 1 | 1 | 1 | 0 | 0 | 1 |
| 40 | 0 | 0 | 0 | 1 | 0 | 1 |
| 41 | 1 | 0 | 0 | 1 | 0 | 1 |
| 42 | 0 | 1 | 0 | 1 | 0 | 1 |
| 43 | 1 | 1 | 0 | 1 | 0 | 1 |
| 44 | 0 | 0 | 1 | 1 | 0 | 1 |
| 45 | 1 | 0 | 1 | 1 | 0 | 1 |
| 46 | 0 | 1 | 1 | 1 | 0 | 1 |
| 47 | 1 | 1 | 1 | 1 | 0 | 1 |
| 48 | 0 | 0 | 0 | 0 | 1 | 1 |
| 49 | 1 | 0 | 0 | 0 | 1 | 1 |
| 50 | 0 | 1 | 0 | 0 | 1 | 1 |
| 51 | 1 | 1 | 0 | 0 | 1 | 1 |
| 52 | 0 | 0 | 1 | 0 | 1 | 1 |
| 53 | 1 | 0 | 1 | 0 | 1 | 1 |
| 54 | 0 | 1 | 1 | 0 | 1 | 1 |

“1” means a square hole on the corresponding position of busbar, the tip of U POSITION PIN is free, and disconnects with L7
“0” means no hole on the corresponding position of busbar, the tip of U POSITION PIN is pressed, and connects with L7

The system controller 1014 may provide commands 1010 to a PSU control circuitry, which may be integrally formed with each PSU or as a separate component shared by the PSUs 1002A-1002N. The commands 1010 may carry position information such as position codes of respective PSUs, to which the system controller 1014 intended to send the commands.

The PSUs may receive a different input depending on their positions on the mating structure. For example, the PSUs may receive a supply voltage and/or a return path depending on their positions on the busbar, such that each PSU differs in these parameters based on its position along the busbar. In some embodiments, the identified positions may be used to re-configure the PSUs such that the voltage and/or current output by the PSUs are as desired and not affected by the position-dependent variations of such parameters. Each PSU may identify its position and re-configure internal circuits based on the identified positions. Alternatively or additionally, a system controller may identify a PSU's position based on the position code received from the PSU and send a command for re-configuring the PSU or otherwise effect position-dependent control. As an example, the PSUs may be re-configured by adjusting their input and/or output impedances based on the identified positions, such that the PSUs can provide desired levels of power.

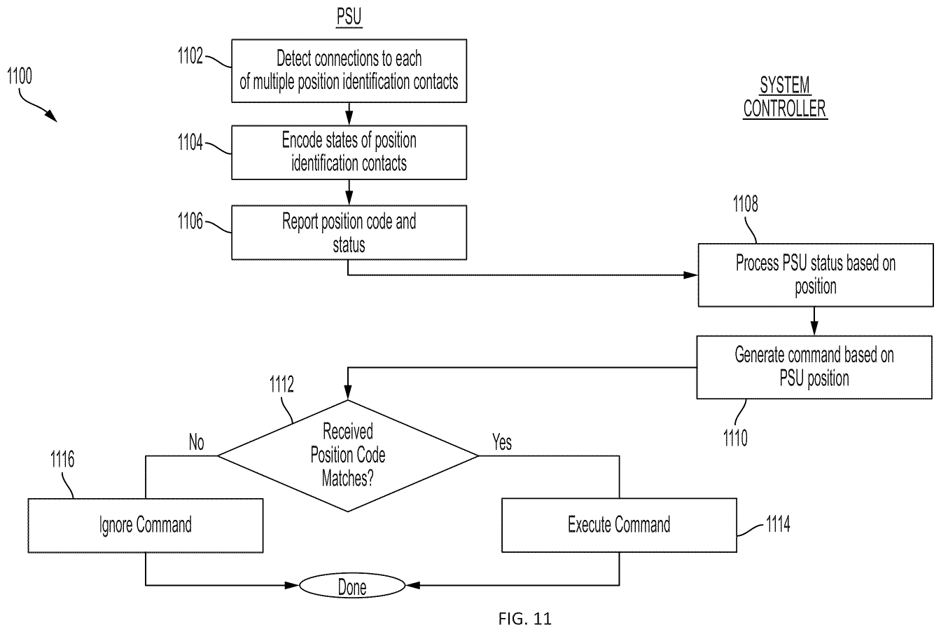

FIG. 11 shows a method 1100 of determining a position of a connector (e.g., the connector 300) on a mating structure (e.g., the busbar 110). The method 1100 may start by a PSU detecting connections to each of multiple position identification contacts at step 1102. At step 1104, the PSU may encode states of the position identification contacts. At step 1106, the PSU may report the position code to, for example, a system controller. In some embodiments, the PSU may generate and report its status to the system controller, and the status report may be coupled with the position report such that the controller may associate a reported status with a PSU in an identified position.

At step 1108, the system controller may process the status of the PSU based on the position code. In some examples, the processing may include displaying the status of the PSU in conjunction with position information based on the received position code. The display may be on a user interface for the system controller. Alternatively or additionally, at step 1110, the system controller may generate a command based on the status and the identified position of the PSU. The command, for example, may be tagged with the position code. The command may set or change a programmable operating parameter of the identified PSU, such as the voltage out, current limit, etc.

At step 1112, the PSU may receive the command from the system controller and compare the position code carried by the command with the position code generated by itself. If the PSU determines that the position code carried by the command from the system controller matches the position code generated by itself, the PSU proceeds to execute the command at step 1114. If the PSU determines that the position code carried by the command from the system controller does not match the position code generated by itself, the PSU ignores the command at step 1116 since the command is not meant for the PSU.

In some embodiments, the identified positions and/or statuses of a component (e.g., a PSU and/or a connector coupling the PSU to the busbar) may be provided to a user interface, which may be accessible by an operator. The statuses may include information about corresponding actions that should be taken by the operator, such as maintaining or replacing the component, which may be displayed on the user interface. The identified positions may enable the operator to access a problematic component among a large number of components in a system within desired time limitations. Such position information may advantageously accelerate maintenance on the system in scenarios in which some or all of the PSUs are integrated into a system in which visual and/or audio status indicators would be ineffective. Such a scenario may arise if some or all of the PSUs are partially or totally hidden from view such that the operator is unable to easily see visual status indicators on the PSU to determine which PSU requires repair or replacement. For example, multiple PSUs may be inside a tank of cooling liquid such that visual and audio alerts on the PSU itself may be ineffective.

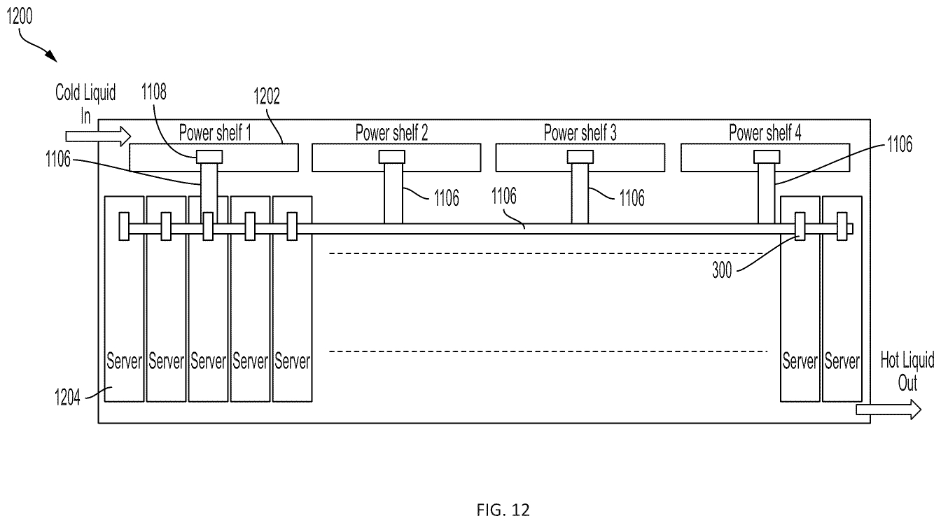

FIG. 12 illustrates an exemplary tank 1200 that may be among the thousands of tanks in a data center. The tank 1200 may include multiple power shelves 1202 and servers 1204. A busbar 1106 may distribute power out of the power shelves 1202. The busbar 1106 may be coupled to the power shelves 1202 via connectors 1108. The position along the busbar of each power shelf may be indicated by outputs of connectors 1108, as described above. The servers 1204 may be coupled to the busbar 1106 via the connectors 300. As discussed with respect to FIGS. 10 and 11, the servers' positions on the busbar 1106 may be identified through the identification of the positions of the connectors 300 on the busbar 1106. The identified positions may be provided to a user interface accessible by qualified operators. In some embodiments, the status information about the servers 1204 and/or connectors 300, such as quality information about the connections between individual connectors 300 and the busbar, may be provided to the user interface such that the operator may take actions based on status, such as repairing or replacing defective units.

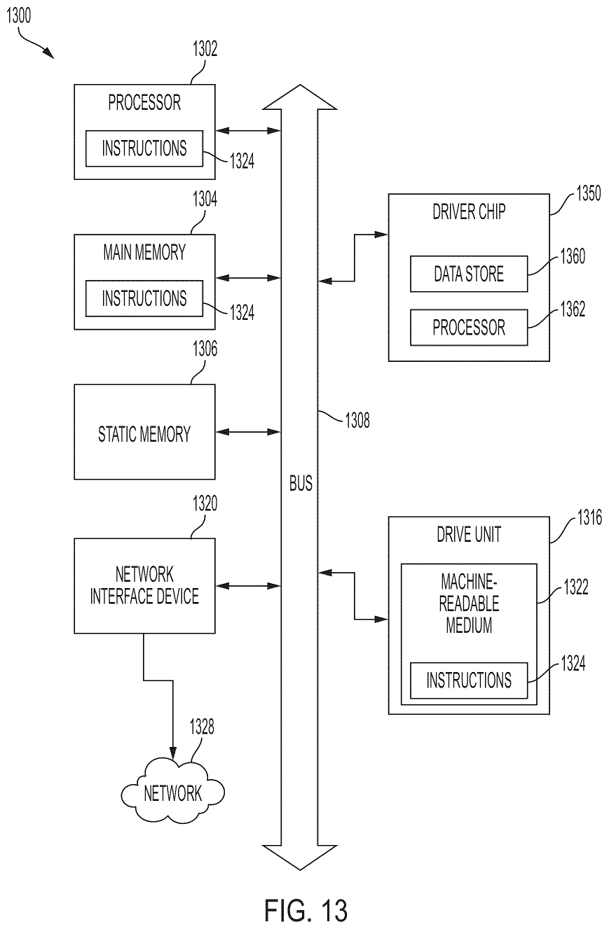

FIG. 13 shows a diagrammatic representation of a machine in the exemplary form of a computer system 1300 within which a set of instructions, for causing the machine to perform any one or more of the methodologies discussed herein, may be executed, according to some embodiments. In alternative embodiments, the machine operates as a standalone device or may be connected (e.g., networked) to other machines. Further, while only a single machine is illustrated, the term “machine” shall also be taken to include any collection of machines that individually or jointly execute a set (or multiple sets) of instructions to perform any one or more of the methodologies discussed herein. Computer system 1300 may represent a system controller or a power supply controller. In that example, the computer system 1300 may be programmed to implement system control or PSU control based on position information as described above.

The exemplary computer system 1300 includes a processor 1302 (e.g., a central processing unit (CPU), a graphics processing unit (GPU) or both), a main memory 1304 (e.g., read only memory (ROM), flash memory, dynamic random access memory (DRAM) such as synchronous DRAM (SDRAM) or Rambus DRAM (RDRAM), etc.), and a static memory 1306 (e.g., flash memory, static random access memory (SRAM), etc.), which communicate with each other via a bus 1308.

The computer system 1300 may further include a disk drive unit 1316, and a network interface device 1320.

The disk drive unit 1316 includes a machine-readable medium 1322 on which is stored one or more sets of instructions 1324 (e.g., software) embodying any one or more of the methodologies or functions described herein. The software may also reside, completely or at least partially, within the main memory 1304 and/or within the processor 1302 during execution thereof by the computer system 1300, the main memory 1304 and the processor 1302 also constituting machine-readable media.

The software may further be transmitted or received over a network 1328 via the network interface device 1320.

The computer system 1300 includes a driver chip 1350 that is used to drive projectors to generate light. The driver chip 1350 includes its own data store 1360 and its own processor 1362.

While the machine-readable medium 1322 is shown in an exemplary embodiment to be a single medium, the term “machine-readable medium” should be taken to include a single medium or multiple media (e.g., a centralized or distributed database, and/or associated caches and servers) that store the one or more sets of instructions. The term “machine-readable medium” shall also be taken to include any medium that is capable of storing, encoding, or carrying a set of instructions for execution by the machine and that causes the machine to perform any one or more of the methodologies of the present disclosure. The term “machine-readable medium” shall accordingly be taken to include, but not be limited to, solid-state memories, optical and magnetic media, and carrier wave signals.

In accordance with various embodiments, communication network 1328 may be a local area network (LAN), a cell phone network, a Bluetooth network, the internet, or any other such network.

Although details of specific configurations of power connectors are described above, it should be appreciated that such details are provided solely for purposes of illustration, as the concepts disclosed herein are capable of other manners of implementation. In that respect, various connector features described herein may be used in any suitable combination, as aspects of the present disclosure are not limited to the particular combinations shown in the drawings.

For example, a connector designed to be attached to a printed circuit board was used to illustrate the construction techniques described herein. The same techniques may be used with a connector, also mounted to a printed circuit board, that mates with a connector that is part of a cable assembly. In yet further embodiments, neither a connector with a frame and a housing member as described herein nor a mating connector may be mounted to a printed circuit board.

Having thus described several embodiments, it is to be appreciated various alterations, modifications, and improvements may readily occur to those skilled in the art. Such alterations, modifications, and improvements are intended to be within the spirit and scope of the invention. Accordingly, the foregoing description and drawings are by way of example only.

The above-described embodiments of the present disclosure can be implemented in any of numerous ways. For example, the embodiments may be implemented using hardware, software or a combination thereof. When implemented in software, the software code can be executed on any suitable processor or collection of processors, whether provided in a single computer or distributed among multiple computers. Such processors may be implemented as integrated circuits, with one or more processors in an integrated circuit component, including commercially available integrated circuit components known in the art by names such as CPU chips, GPU chips, microprocessor, microcontroller, or co-processor. In some embodiments, a processor may be implemented in custom circuitry, such as an ASIC, or semicustom circuitry resulting from configuring a programmable logic device. As yet a further alternative, a processor may be a portion of a larger circuit or semiconductor device, whether commercially available, semi-custom or custom. As a specific example, some commercially available microprocessors have multiple cores such that one or a subset of those cores may constitute a processor. Though, a processor may be implemented using circuitry in any suitable format.

Further, it should be appreciated that a computer may be embodied in any of a number of forms, such as a rack-mounted computer, a desktop computer, a laptop computer, or a tablet computer. Additionally, a computer may be embedded in a device not generally regarded as a computer but with suitable processing capabilities, including a Personal Digital Assistant (PDA), a smart phone or any other suitable portable or fixed electronic device.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format. In some embodiment, the input/output devices may be physically separated from the computing device. In some embodiments, however, the input and/or output devices may be physically integrated into the same unit as the processor or other elements of the computing device. For example, a keyboard might be implemented as a soft keyboard on a touch screen. In some embodiments, the input/output devices may be entirely disconnected from the computing device, and functionally integrated through a wireless connection.

Such computers may be interconnected by one or more networks in any suitable form, including as a local area network or a wide area network, such as an enterprise network or the Internet. Such networks may be based on any suitable technology and may operate according to any suitable protocol and may include wireless networks, wired networks or fiber optic networks.

Also, the various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, the disclosure may be embodied as a computer readable storage medium (or multiple computer readable media) (e.g., a computer memory, one or more floppy discs, compact discs (CD), optical discs, digital video disks (DVD), magnetic tapes, flash memories, circuit configurations in Field Programmable Gate Arrays or other semiconductor devices, or other tangible computer storage medium) encoded with one or more programs that, when executed on one or more computers or other processors, perform methods that implement the various embodiments of the disclosure discussed above. As is apparent from the foregoing examples, a computer readable storage medium may retain information for a sufficient time to provide computer-executable instructions in a non-transitory form. Such a computer readable storage medium or media can be transportable, such that the program or programs stored thereon can be loaded onto one or more different computers or other processors to implement various aspects of the present disclosure as discussed above. As used herein, the term “computer-readable storage medium” encompasses only a computer-readable medium that can be considered to be a manufacture (i.e., article of manufacture) or a machine. In some embodiments, the disclosure may be embodied as a computer readable medium other than a computer-readable storage medium, such as a propagating signal.

The terms “program” or “software” are used herein in a generic sense to refer to any type of computer code or set of computer-executable instructions that can be employed to program a computer or other processor to implement various aspects of the present disclosure as discussed above.

Additionally, it should be appreciated that according to one aspect of this embodiment, one or more computer programs that when executed perform methods of the present disclosure need not reside on a single computer or processor, but may be distributed in a modular fashion amongst a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that conveys relationship between the fields. However, any suitable mechanism may be used to establish a relationship between information in fields of a data structure, including through the use of pointers, tags or other mechanisms that establish relationship between data elements.

Various changes may be made to the illustrative structures shown and described herein.

For example, position identification contacts were described as interacting with a mating component configured with a pattern of openings such that, where there is no opening aligned with a position identification contact, the position identification contact will be pressed by the mating component into a loop contact to activate the position sense contact. In other implementations, the mating component, such as a busbar shell, may have features of other types in each of multiple connector mating positions that interact with the position identification contacts, such as embossments, tabs, insulative nubs or other projecting structures. Where such a projecting structure is present, the position identification contact may be forced into contact with a loop contact. Where no such projecting structure is present, the position identification contact may remain separate from the loop contact.

As a further example, an illustrative partitioning of processing of the states of position identification contacts was described in connection with FIG. 10. The processing may be partitioned in other ways. A PSU, for example, may directly report its status along with a position code to a controller or other component outside the rack and receive commands addressed based on position code from a controller outside the rack.

As yet another example, it was described that a pattern of activated and un-activated states of position identification contacts for one connector could be encoded to a position code. Encoding may be simply performed by generating a binary code in which each bit position is assigned a binary value depending on whether a position identification contact is activated or un-activated. In other examples, encoding may map patterns of activated and un-activated states of the position identification contacts to symbols, words or other constructs. Moreover, the encoding need not be one-to-one. Multiple patterns of activated and un-activated states, for example, may be mapped to the same code.

As a further example, position identification contacts were described in connection with a multifunction connector. Position identification contacts may alternatively or additionally be used to sense the mating position of a component inserted into a rack or other support structure, without being integrated into a multifunction connector.

As yet another example, busbars are illustrated as having a length along an axis of elongation that is substantially longer than the height of a connector in a direction parallel to the axis of elongation. Such a configuration is common in systems in which, for example, the busbars supply power to multiple daughtercards mated to the same backplane. However, it is not a requirement that the busbars extend the entire length of the backplane or even that the busbars provide power to multiple daughtercards. In some embodiments, the busbars to which a connector as described herein may themselves be within a connector. Those busbars may be electrically coupled to power planes within a printed circuit board, such as a backplane, or may be coupled to a source of power through cables.

As an example of another variation, a connector is described as being configured for distribution of power from busbars to components on one or more daughtercards. It should be appreciated, however, that the direction of power flow is provided for simplicity of explanation. Power might be coupled through the connector to the busbars.

Furthermore, although many inventive aspects are shown and described with reference to a power connector, it should be appreciated that aspects of the present disclosure is not limited in this regard, as any of the inventive concepts, whether alone or in combination with one or more other inventive concepts, may be used in other types of electrical connectors, such as right angle connectors, mezzanine connectors, cable connectors, stacking connectors, I/O connectors, chip sockets, etc.

The present disclosure is not limited to the details of construction or the arrangements of components set forth in the foregoing description and/or the drawings. Various embodiments are provided solely for purposes of illustration, and the concepts described herein are capable of being practiced or carried out in other ways. Also, the phraseology and terminology used herein are for the purpose of description and should not be regarded as limiting. The use of “including,” “comprising,” “having,” “containing,” or “involving,” and variations thereof herein, is meant to encompass the items listed thereafter (or equivalents thereof) and/or as additional items.

In some embodiments, dimensions or other values are described as being the same or “equal.” It should be understood that in practical systems and devices, values that are considered equal are not always mathematically identical as practical components and products will be produced with tolerances. Accordingly, values may be regarded as the same or equal may differ within some tolerance allowable for a given application, which may be within ±20% in some embodiments, within ±10% in some embodiments, within ±5% in some embodiments, and yet within ±2% in some embodiments.

Further, it should be understood that when values are given, they are, unless context specifies otherwise, measured in accordance with an applicable measurement technique known in the art.

What is claimed is:

1. An electronic system comprising:
a subassembly;
a support structure comprising a plurality of positions, each of the plurality of positions configured to receive a subassembly; and
a controller, wherein:
the subassembly is installed in the support structure at a position of the plurality of positions,
the subassembly is configured to interact with the support structure at the position of the plurality of positions and generate an indication of the position of the plurality of positions in which the subassembly is installed, and
the subassembly is configured to communicate status and/or control information with the controller, the status and/or control information being associated with position information generated based on the indication of the position.

2. The electronic system of claim 1, wherein:
the subassembly comprises an electrical connector,
each position of the support structure comprises a mating component configured to mate with the electrical connector, and
the electrical connector is configured to output the indication of the position.

3. The electronic system of claim 2, wherein:
the support structure comprises a busbar, and
the electrical connector is a power connector configured to mate with the busbar.

4. The electronic system of claim 1, wherein:
the subassembly is a power supply unit, and
the power supply unit is configured to report, to the controller, a status of the power supply unit in conjunction with an identified position of the power supply unit.

5. The electronic system of claim 4, wherein the controller is configured to generate commands to the power supply unit based on the identified position.

6. The electronic system of claim 5, wherein the commands to the power supply unit based on the identified position are based on a voltage drop between a voltage source and the position.

7. The electronic system of claim 5, wherein the commands to the power supply unit based on the identified position are based on a length of a conducting path between the position and a load.

8. The electronic system of claim 5, wherein the power supply unit is configured to determine whether a position code carried by the commands matches the position code generated by the power supply unit,
when it is determined that the position codes do not match, ignore the commands received from the controller, and
when it is determined that the position codes match, execute the commands received from the controller.

9. The electronic system of claim 1, further comprising:
a user interface, wherein:
the controller is configured to present on the user interface the status information for the subassembly based on the position information generated based on the indication of the position.

10. The electronic system of claim 9, wherein:
the controller is configured to identify a subassembly in a fault state and display on the user interface an indication of the subassembly with the fault and a position of the subassembly.

11. The electronic system of claim 10, wherein:
the support structure comprises a rack, and
the plurality of positions are slots within the rack.

12. The electronic system of claim 9, wherein:
the controller is remote from the support structure, and
the electronic system comprises a network connecting the controller to the subassembly.

13. An electronic system comprising:
a power supply unit configured to:
generate a position code based on a position within the electronic system in which the power supply unit is installed,
generate status information, and
transmit the status information associated with the position code; and
a controller comprising a non-transitory computer readable storage medium comprising computer executable instructions configured to, when executed:
receive, from the power supply unit, the position code and the status information, process the status information to generate a result, and
associate the result with a position within the electronic system.

14. The electronic system of claim 13, wherein:
the power supply unit is a first power supply unit,
the system comprises a plurality of power supply units, including the first power supply unit, and
processing the status information to generate the result comprises reporting the status of the first power supply unit differentiated from others of the plurality of power supply units based on the position code.

15. The electronic system of claim 13, wherein:
the power supply unit is a first power supply unit,
the electronic system comprises a plurality of power supply units, including the first power supply unit,
the controller is configured to communicate with the plurality of power supply units, and the first power supply unit is configured to:
receive commands from the controller,
determine whether a position code carried by the received commands matches the position code generated by the first power supply unit,
when it is determined that the position codes do not match, ignore the received commands, and
when it is determined that the position codes match, execute the received commands.

16. The electronic system of claim 13, further comprising:
a user interface coupled to the controller, wherein the computer executable instructions are further configured to, when the result indicates a fault of the power supply unit, present the result on the user interface in connection with a position of the power supply unit.

17. An electronic system comprising:
a busbar;
a plurality of connectors mated to the busbar, each of the plurality of connectors configured to provide one or more signals indicating a position of the connector on the busbar;
a user interface; and
a controller configured to provide on the user interface status information indicating status within the electronic system in combination with information indicating a position within the system of the status, wherein the controller is configured to generate the information indicating the position based on the one or more signals indicating the position on the busbar of at least one connector of the plurality of connectors.

18. The electronic system of claim 17, wherein:
each of the plurality of connectors is configured to provide a status of a connection between the connector and the busbar, and
the statuses of the connections between individual connectors and the busbar are provided to the user interface.

19. The electronic system of claim 17, wherein:
the controller is configured to execute computer executable instructions to:
receive, from each of the plurality of connectors, the one or more signals indicating the position of the connector on the busbar,
compute the positions of the plurality of connectors on the busbar based on the received signals, and
provide the positions of the plurality of connector on the busbar to the user interface.

20. The electronic system of claim 17, wherein:
each of the plurality of connectors is associated with a respective subassembly of a plurality of subassemblies,
the status information comprises status information of the subassembly, and
the status information comprises an indication of a fault within a subassembly of the plurality of subassemblies.
